(19) United States
(12) Patent Application Publication
(10) Pub. No.: US 2006/0008033 A1
(43) Pub. Date: Jan. 12, 2006

(54) Demodulation of a frequency-modulated received signal by mapping the zero crossings to a sequence of parameter values

(76) Inventors: Jurgen Niederholz, Kerken (DE); Andre Neubauer, Krefeld (DE)

Correspondence Address: ESCHWEILER & ASSOCIATES, LLC;NATIONAL CITY BANK BUILDING, 629 EUCLID AVE., SUITE 1210, CLEVELAND, OH, 44114, US

(21) Appl. No.: 11/176,459

(22) Filed: Jul. 7, 2005

Related U.S. Application Data
(63) Continuation of application No. PCT/DE03/04279, filed on Dec. 23, 2003.

(30) Foreign Application Priority Data
Jan. 8, 2003 (DE) DE 103 00 267.7

(51) Int. Cl. H03D 1/00

(52) U.S. Cl. 375/341

(57) ABSTRACT

A detector for zero crossings determines the zero crossings in the received signal or in an intermediate frequency signal which is generated from the received signal. Since, in the case of frequency-modulated signals, the number of zero crossings per symbol interval is naturally not constant, the zero crossing sequence is mapped to a sequence {zᵢ} of parameter values zᵢ which are at equidistant time intervals by means of mathematical, non-linear mapping. Mean value formation of zero crossing intervals or determination of the number of zero crossings can be used for mapping. The sequence of parameter values zᵢ at equidistant time intervals can be supplied to a conventional detection algorithm such as a Viterbi detection algorithm.

### REFERENCE TO RELATED APPLICATIONS

This application is a continuation of PCT/DE03/04279, filed on Dec. 23, 2003, which was not published in English, which claims the benefit of the priority date of German Patent Application No. DE 103 00 267.7, filed on Jan. 8, 2003, the contents of which both are herein incorporated by reference in their entireties.

### FIELD OF THE INVENTION

The present invention relates to a method and an apparatus for demodulating an analog received signal which has been transmitted via radio and has been frequency-modulated with a data symbol sequence at the transmitter end.

### BACKGROUND OF THE INVENTION

In communication systems based on Bluetooth standard, the DECT standard, the WDCT standard or a similar standard of this type, traditional signal processing methods are used, at the receiver end, to demodulate the frequency-modulated received signal and to detect signals. A method that is frequently used is based on the “limiter/discriminator FM demodulator” in which, after hard limiting of the generally complex bandpass signal, the frequency-modulated signal is demodulated, for example by an analog coincidence demodulator, with corresponding signal detection.

Receiver designs in which an analog/digital converter is used to convert the intermediate frequency signal to the digital domain and digital signal processing methods are used to detect signals are also known. Such a method is described, for example, in document DE 101 03 479.3. Although methods of this type can be used to achieve high-quality signal detection, they have the disadvantage of a complex analog/digital converter.

Document DE 102 14 581.4 describes a method for demodulating an analog received signal (which has been digitally frequency-modulated) in a cordless communication system, in which the time intervals between the zero crossings in the received signal or in an intermediate frequency signal that is generated from the received signal are determined and are used to detect the digital signal data. The data symbols {dₖ} in a CPFSK-modulated (Continuous Phase Frequency Shift Keying) signal are detected by splitting the data symbol sequence into subsections which contain a plurality of zero crossings and the length of which may cover a plurality of symbol intervals. The sequence of zero crossing intervals can be stored in digital form in a shift register chain and can be compared, in a classification device, with previously stored interval sequences, a city block metric being proposed for measuring the distance between the measured sequences and the stored sequences. That previously stored pattern sequence which is at the shortest distance from the measured sequence is interpreted as the transmitted pattern. The data sequence corresponding to this selected pattern constitutes the detected data sequence and thus the solution to the detection problem.

In the demodulation method which is described in document DE 102 37 867.3, a sequence of zero crossing intervals (which have been determined) in the received signal is taken as the basis for reconstructing the data symbol sequence by selecting from the possible data symbol sequences, as the data symbol sequence which is sought, that data symbol sequence for which the Euclidean distance between the sequence of zero crossing intervals and a sequence calculated at the receiver end is minimal. A Viterbi algorithm which has been suitably extended by a reactive component (reactive Viterbi algorithm) is used during reconstruction. In this case, when calculating the branch metric, the varying number of zero crossings is taken into account, and the entire received sequence (instead of only subsequences) is thus assessed. The disadvantage of this is that an inherent assumption about the transmitted data needs to be made when calculating the branch metrics. This leads to an additive error component in the branch metric.

In addition, both of the previously described demodulation methods have the inherent problem that the number of zero crossings in a symbol interval fluctuates on the basis of the data, some known system parameters and unknown interfering influences. However, conventional digital receiver designs always presuppose a fixed number of samples per symbol interval.

Document U.S. Pat. No. 5,469,112 describes a demodulation method in which the received signal is split into an in-phase branch and a quadrature branch, and the received signal is mixed with the output signal from a local oscillator, said output signal being supplied to one of the two branches following a phase shift through 90°. After passing through a low-pass filter and a limiter, the two signals are supplied to a zero crossing detector. A phase angle estimator which contains a bidirectional counter determines the direction of the phase change in the I and Q signals at the zero crossing and uses the result to detect the data symbol sequence. However, implementation of the phase angle estimator and of the counter integrated in the latter is a relatively complex solution.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present one or more concepts of the invention in a simplified form as a prelude to the more detailed description that is presented later.

The present invention is directed to a method and an apparatus for demodulating a received signal (which has been digitally frequency-modulated) which are able to be used to achieve a high level of performance in conjunction with simultaneously low implementation complexity.

Accordingly, the present invention relates to a method for demodulating an analog received signal which has been frequency-modulated with a data symbol sequence at the transmitter end. The zero crossings in the received signal or in an intermediate frequency signal which is generated from the received signal are first of all detected. As explained initially, one aspect of the present invention is to map the sequence of zero crossings which are not at equidistant time intervals to a sequence of parameter values which are at equidistant time intervals and the number of which per symbol interval is constant. This sequence of parameter values at equidistant time intervals can then be subsequently used to reconstruct the transmitted data symbol sequence using a conventional detection algorithm.

The demodulation method according to one embodiment of the invention comprises (a) detecting zero crossings in the received signal, and (b) generating a sequence of parameter values which are at equidistant time intervals, the number of which per symbol interval is constant, and which are generated by means of mathematical, particularly non-linear, mapping using the zero crossings. The method further comprises (c) using a detection algorithm to reconstruct the data symbol sequence from the sequence of parameter values.

The zero crossings that are observed and are within a symbol interval [kT_{b}, (k+1)T_{b}] are thus mapped to a fixed number of samples or parameter values zᵢ which then form a sequence {zᵢ} and are subsequently be supplied to a detection algorithm, for example, a Viterbi sequence detection algorithm. Such mathematical, particularly non-linear, mapping thus allows a generally inexpensive and simple intermediate frequency receiver having a limited output to be used in combination with powerful digital receiver designs.

Selecting mathematical non-linear mapping influences the quality and complexity of the entire detection algorithm. In accordance with the invention, a larger number of fixed samples or parameter values per symbol interval allows the parameter value sequence {zᵢ} to describe the zero crossing sequence {tᵢ} in a more precise manner. This is then associated with a lower loss of information, and the channel capacity is reduced to a lesser extent. The choice of mapping and thus the number of parameters per symbol interval enables virtually arbitrary adaptation to the requisite quality of the receiver or to the complexity of the latter.

Another advantage of the invention results from the fact that dependencies between the elements (generated in this manner) in the parameter value sequence {zᵢ} can be taken into account during detection. Since the elements in the zero crossing sequence {tᵢ} and in the zero crossing sequences {t₂ᵢ} and {t₂ᵢ₋₁} (of the I and Q components) always have a form of intersymbol interference (thus indicating that successive elements are correlated to one another), the effect of this dependency on the parameter value sequence {zᵢ} is taken into account and can thus be advantageously used in the subsequent detection step (for instance Viterbi sequence detection). In this case, the dependencies (particularly correlations) between the sequence elements zᵢ can be determined analytically or empirically. In any case, the dependencies can be calculated a priori and can thus be stored as a parameter set in a read-only memory, for instance. If appropriate, for example, if all of the parameters have not been perfectly synchronized, it is possible to store various sets of values for various synchronization parameters which have been detected but have not been compensated for.

The mean value of the zero crossing intervals over one symbol interval (or a portion of one symbol interval) may be used as a very simple way of mapping the zero crossings to the parameter sequence {zᵢ} in a non-linear manner. In the method step (b), a zero crossing sequence {t_{φ}} can thus be generated first of all, with a sequence element t_{φ} being determined by the difference φᵢ₊₁−φᵢ between the times φᵢ and φᵢ₊₁ associated with two successive zero crossings. The parameter values for the sequence {zᵢ} are then generated by forming the mean value of a respective number of sequence elements.

In one embodiment of the invention, the received signal is split into an in-phase (I) branch and a quadrature (Q) branch, and the zero crossings are detected and corresponding zero crossing sequences {t₂ᵢ} and {t₂ᵢ₋₁} are generated in each branch. The zero crossing sequences {t₂ᵢ} and {t₂ᵢ₋₁} are then preferably alternately combined to form a sequence {t′ᵢ}, and the parameter sequence {zᵢ} is finally generated from the combined sequence {t′ᵢ}.

If, in this case, the mean value of the zero crossing intervals over one symbol interval is formed, the result is as follows:

$${z}_{i} = \frac{1}{I ( k + 1 ) - I ( k )} {\sum }_{φ = I ( k ) + 1}^{I ( k + 1 )} {t}_{φ}^{′} \qquad ( 1 )$$

where the zero crossing intervals t′_{φ} in the interval [kT_{b}, (k+1)T_{b}] and the index i are a function of the index k and the number of parameters per symbol interval N (for example i=k when N=1).

Another parameter that can be calculated in a simple manner is the number of zero crossings per symbol interval. The following applies to this:
zᵢ=#{t′_{φ}I(k)<φ≦I(k+1} (2)
where i is likewise a function of k and N.

A more complex option is to additionally take the variance in a symbol interval into account. In addition, the gradient per interval, for instance, may also be used. Irrespective of whether one or more parameters are extracted per symbol interval, the correlations between the parameters are determined a priori so that they can then be used in the downstream detection stage (for instance a Viterbi sequence detector).

The choice of parameters and thus the non-linear mapping operation depend on the permitted complexity and the quality required.

To the accomplishment of the foregoing and related ends, the invention comprises the features hereinafter fully described and particularly pointed out in the claims. The following description and the annexed drawings set forth in detail certain illustrative aspects and implementations of the invention. These are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

Exemplary embodiments of the invention will be explained in more detail below with reference to the drawings, in which:

FIG. 1 is a block diagram illustrating an operation of a zero crossing detector;

FIG. 2 is a block diagram illustrating a model of a transmission system containing a reception apparatus for carrying out the method according to the invention; and

FIG. 3 illustrates a transmitted data symbol sequence, a resultant zero crossing sequence and the mapping of these to a parameter sequence according to one exemplary embodiment of the invention.

### DETAILED DESCRIPTION OF THE INVENTION

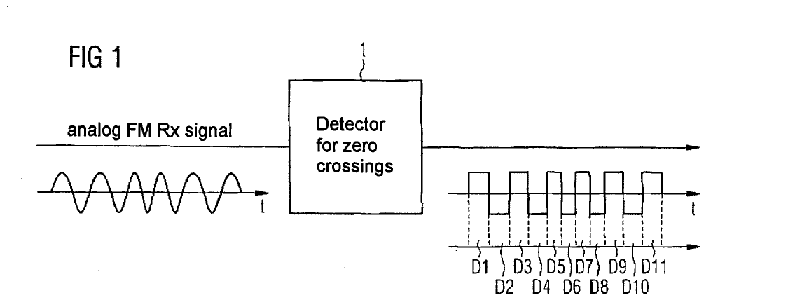

FIG. 1 shows how a zero crossing detector 1 is used to convert an analog received signal, which, for example, is in the intermediate frequency range, into a square-wave signal, the zero crossings of which are to be evaluated. The zero crossings themselves, for instance the number of them per symbol interval (or portion of the symbol interval), or the time interval Dᵢ between the zero crossings in the square-wave signal, averaged over one symbol interval, can be used for signal detection in accordance with the invention.

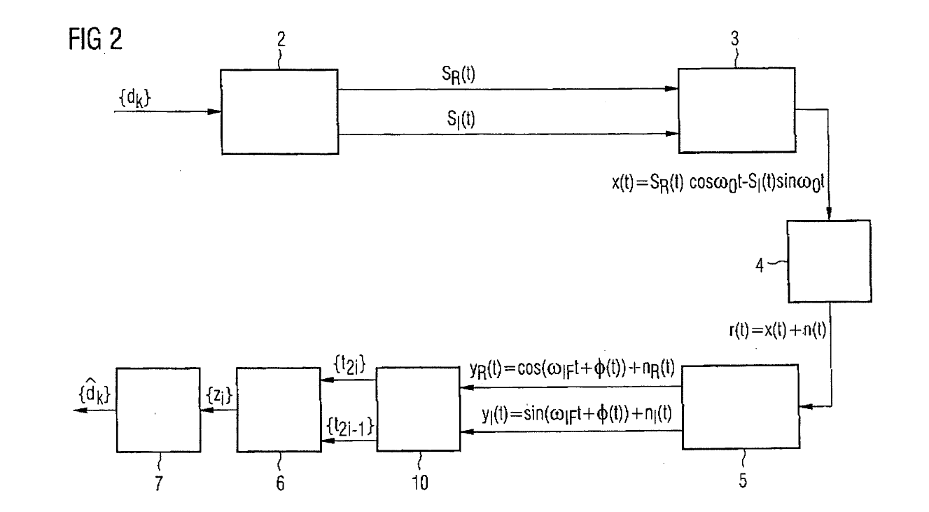

FIG. 2 shows a model of a frequency-modulating transmission system whose reception apparatus is part of the present invention. At the transmitter end, a data symbol sequence {dₖ} which is to be transmitted is supplied to a modulator 2. Quadrature modulation is carried out in the modulator 2 and generates an I signal s_{R}(t) and a Q signal s_{I}(t). Both signals are supplied to a radio-frequency part 3 in which a radio-frequency carrier oscillation is modulated onto the two baseband signals, and the signals are combined to form a single signal x(t) and are emitted. The baseband signals can, for example, be CPFSK-modulated in the radio-frequency part 3. The signal x(t) is then transmitted via a transmission channel 4 in which a noise component n(t) is added to the transmitted signal x(t).

At the reception end, the received signal r(t) is supplied to a reception radio-frequency part 5 in which quadrature demodulation is simultaneously carried out. Quadrature demodulation splits the signal into an I branch and a Q branch and mixes it, in each of the branches, with an intermediate frequency which is supplied to the Q branch with a phase shift of 90° with respect to the I branch. The signals x_{R}(t) and x_{I}(t) which are generated in this manner are supplied to a limiter/discriminator 10. The limiter/discriminator 10 is one embodiment of the zero crossing detector 1 and thus provides corresponding zero crossing sequences {t₂ᵢ} and {t₂ᵢ₋₁}, that is to say the corresponding times of the zero crossings in the two signals, at its two outputs. These zero crossing sequences are supplied to a mathematical processing unit 6 which mathematically maps the combined zero crossing sequences to a parameter sequence {zᵢ} in a non-linear manner. In this case, in the processing unit 6, the combined zero crossing sequence may first of all be used to form zero crossing intervals, that is to say differences between successive zero crossing times, and the difference sequence formed in this manner can be mapped to the parameter sequence. The parameter values for the parameter sequence {zᵢ} are finally supplied to a Viterbi sequence detector 7 in which conventional Viterbi sequence detection is carried out in order to determine the data symbol sequence.

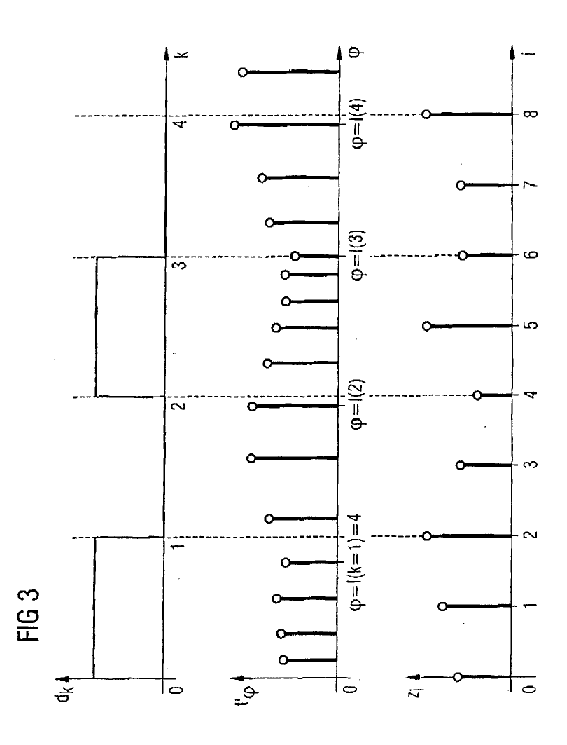

FIG. 3 shows one example of an inventive operation of mapping a data symbol sequence to a zero crossing sequence and to a parameter sequence. In the exemplary embodiment, at the reception end, a transmitted data symbol sequence {dₖ} is used to generate a zero crossing sequence {t′_{φ}} which is combined from the zero crossing sequences in the I and Q signals. In the present example, differences between the zero crossing times are formed, and not only is the mean value of the differences formed but also the number of zero crossings is determined, and the two parameters are mapped to the parameter sequence {zᵢ}. The parameter sequence {zᵢ} having N=2 parameter values per symbol interval is thus derived from the zero crossing sequence {t′_{φ}} through mean value formation and number determination. In this case, i=2k in equation (1) and i=2k+1 in equation (2).

Both parameters are mapped to the parameter sequence {zᵢ} by alternately using both equations, to be precise using each equation once per symbol interval. The first zᵢ per symbol interval is thus defined by equation (1) and the second zᵢ in the same symbol interval is defined by equation (2).

While the invention has been illustrated and described with respect to one or more implementations, alterations and/or modifications may be made to the illustrated examples without de-parting from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

1. A method for demodulating an analog received signal which has been frequency-modulated with a data symbol sequence {dₖ} at the transmitter end, comprising:
(a) detecting zero crossings in the received signal;
(b) generating a sequence {zᵢ} of parameter values zᵢ that are at equidistant time intervals, wherein the number of parameter values zᵢ per symbol interval is constant, and wherein the parameter values sequence {zᵢ} is generated by a mathematical, non-linear mapping using the detected zero crossings; and
(c) using a detection algorithm to reconstruct the data symbol sequence from the parameter values sequence {zᵢ}.

2. The method of claim 1, wherein the detection algorithm comprises Viterbi detection.

3. The method of claim 1, wherein act (b) further comprises:
(b.1) generating a sequence {t_{φ}}, wherein a sequence element t_{φ} comprises a difference φᵢ₊₁−φᵢ between times φᵢ and φᵢ₊₁ associated with two successive detected zero crossings; and
(b.2) generating the parameter values zᵢ for the sequence {zᵢ} by forming a mean value of a respective number of sequence elements t_{φ}.

4. The method of claim 1, wherein the mathematical, non-linear mapping in act (b) is determined by the number of zero crossings per symbol interval or per a portion of a symbol interval.

5. The method of claim 1, wherein:
the received signal is split into an in-phase (I) branch and a quadrature (Q) branch, and the zero crossings are detected and corresponding sequences {t₂ᵢ}, {t₂ᵢ₋₁} are generated in each branch in accordance with act (a);
combining the sequences {t₂ᵢ} and {t₂ᵢ₋₁} to form a sequence {t′_{φ}}; and
generating the sequence {zᵢ} from the combined sequence.

6. The method of claim 1, wherein the frequency-modulated received signal comprises a CPFSK signal.

7. An apparatus for demodulating an analog received signal that has been frequency-modulated with a data symbol sequence {dₖ} at the transmitter end, comprising:
a detector configured to detect zero crossings in the received analog signal;
a mathematical processing unit configured to generate a parameter values sequence {zᵢ} by a non-linear mapping using the detected zero crossings; and
a detection unit configured to detect a data symbol sequence {dₖ} using the sequence {zᵢ} of parameter values.

8. The apparatus of claim 7, wherein the detection unit comprises a Viterbi sequence detector.

9. The apparatus of claim 7, wherein the mathematical processing device is configured to determine time differences between successive zero crossings and form a mean value of a number of such time differences for use in performing the mapping.

10. The apparatus of claim 7, wherein the mathematical processing unit is configured to determine a number of zero crossings.

11. The apparatus of claim 7, wherein the apparatus is configured to perform quadrature demodulation of in-phase (I) and quadrature (Q) signal components, and wherein the detector or the mathematical processing unit are configured to combine the zero crossing sequences in the I and Q signals to form a common zero crossing sequence.

12. The apparatus of claim 11, further comprising a reception radio-frequency component configured to down-mix the I signal component and the Q signal component to an intermediate frequency.

13. The apparatus of claim 7, wherein the zero crossing detector comprises a limiter/discriminator.

14. A method of demodulating an analog received signal which has been frequency-modulated with a data symbol sequence {dₖ} at the transmitter end, comprising:
detecting zero crossings in the received signal;
mapping the detected zero crossings to a parameter value sequence; and
reconstructing the data symbol sequence using the parameter value sequence.

15. The method of claim 14, wherein the detected zero crossings do no occur at equidistant time intervals with respect to one another.

16. The method of claim 16, wherein the parameter value sequence comprises a sequence of parameters that are at equidistant time intervals.

17. The method of claim 16, wherein a number of parameter values per symbol interval is constant.

18. The method of claim 14, wherein the mapping comprises a non-linear mapping.

19. The method of claim 14, wherein mapping the detected zero crossings to the parameter value sequence comprises:
determining a difference in time between a plurality of successive detected zero crossings;
generating a sequence of the determined time differences; and
generating parameter values for a parameter value sequence by calculating a mean value associated with various predetermined numbers of elements of the time differences sequence.

20. The method of claim 14, wherein:
the received signal is split into an in-phase (I) branch and a quadrature (Q) branch, and the zero crossings are detected and corresponding sequences {t₂ᵢ}, {t₂ᵢ₋₁} are generated in each branch, further comprising:
combining the sequences {t₂ᵢ} and {t₂ᵢ₋₁} to form a sequence {t′_{φ}}; and
generating the parameter value sequence from the combined sequence.
